(19) United States
(12) Patent Application Publication
(10) Pub. No.: US 2012/0145230 A1
(43) Pub. Date: Jun. 14, 2012

(54) SOLAR CELL AND SOLAR CELL DEVICE

(76) Inventors: Kazushi Hiraoka, Osaka-shi (JP); Iwao Sugimoto, Osaka-shi (JP); Toshio Takiya, Osaka-shi (JP); Kouji Takanabe, Osaka-shi (JP)

(21) Appl. No.: 13/390,530

(22) PCT Filed: Jul. 16, 2010
(86) PCT No.: PCT/JP2010/062036

§ 371 Date: Feb. 15, 2012

(30) Foreign Application Priority Data
Aug. 20, 2009 (JP) 2009-190559

(51) Int. Cl. H01L 31/02; B82Y 99/00

(52) U.S. Cl. 136/252; 977/948

(57) ABSTRACT

Provided is a solar cell including: a transparent electrode (2) formed as an n-type semiconductor; a plurality of carbon nanotube groups (3) placed in parallel to each other on and perpendicularly to the lower surface of the transparent electrode (2); and metal electrodes (4) placed on the lower surfaces of the carbon nanotube groups (3) opposite to the electrode (2). The diameters of the carbon nanotubes of the carbon nanotube groups (3) in parallel to each other are varied from one side of the electrode (2) to the other side thereof, and the group III atoms are doped into the carbon nanotube groups to form p-type semiconductors.

### TECHNICAL FIELD

The present invention relates to a solar cell using carbon nanotubes and a solar cell device using the solar cell.

### BACKGROUND ART

The most common solar cells are monocrystalline, polycrystalline, and amorphous silicon solar cells, which have been spreading into homes and businesses. However, these silicon solar cells are disadvantageously low in energy conversion efficiency. One of the factors in the disadvantage is that the common solar cell has only one band gap. Long-wavelength light having energy below the bad gap cannot undergo photoelectric conversion, but conversely, short-wavelength light having energy above the band gap can undergo photoelectric conversion for only the amount of energy equivalent to the band gap.

In order to deal with such a disadvantage, a solar cell having at least two different band gaps has been proposed (for example, see Japanese Patent Application Laid-Open Publication No. 2003-197930).

### SUMMARY OF INVENTION

### Technical Problem

In order to increase the energy conversion efficiency as described above, as shown in the Japanese Publication, it is considered that a solar cell is provided with at least two band gaps, in other words, multiple band gaps.

However, it is difficult for a semiconductor using crystal such as silicon to obtain any band gaps, since band gaps are fixed by the selection of elements including compound semiconductors. Thus, the energy conversion efficiency cannot be increased. Further, in tandem or superposed solar cells, the solar cell in the upper layer absorbs and scatters the sunlight, thereby attenuating light required for the lower solar cells.

Hence, an object of the present invention is to provide a solar cell and a solar cell device which can increase the energy conversion efficiency.

### Solution to Problem

In order to solve the above problems, a first aspect of the present invention is a solar cell including: a transparent electrode; a plurality of carbon nanotube groups placed in parallel to each other on and perpendicularly to the surface of the transparent electrode, wherein each group contains a number of carbon nanotubes; and metal electrodes placed on the carbon nanotube groups opposite to the transparent electrode, wherein the diameters of the carbon nanotubes of the carbon nanotube groups in parallel to each other are varied stepwise from one side of the transparent electrode to another side thereof.

A second aspect of the present invention is the solar cell according to the first aspect, wherein the transparent electrode is formed as an n-type semiconductor, and the group III atoms of the periodic table are doped into the carbon nanotube groups to make the carbon nanotube groups p-type semiconductors.

A third aspect of the present invention is the solar cell according to the first aspect, wherein the group V atoms of the periodic table are doped into the transparent-electrode-side portions of the carbon nanotube groups to form n-type semiconductors, and the group III atoms of the periodic table are doped into the metal-electrode-side portions of the carbon nanotube groups to form p-type semiconductors.

A fourth aspect of the present invention is the solar cell according to the first aspect, wherein the group V atoms of the periodic table are doped into the carbon nanotube groups to make the carbon nanotube groups n-type semiconductors, and a p-type semiconductor layer is placed between the metal electrodes and the carbon nanotube groups.

A fifth aspect of the present invention is a solar cell device using the solar cell according to the first aspect, the solar cell device including: a spectroscope for splitting the sunlight being placed on the surface of the transparent electrode of the solar cell; and a voltage regulator for regulating electric power obtained by the carbon nanotube groups of the solar cell to a predetermined voltage.

### Advantageous Effects of Invention

In the above-described solar cell and solar cell device, the carbon nanotubes are placed between the transparent electrode and the metal electrodes, and the diameters of the carbon nanotubes are varied stepwise. Thus, it is possible to form the carbon nanotubes in accordance with the respective wavelengths of, for example, the split light beams of the sun light. That is, the carbon nanotubes have any band gaps. Accordingly, since photoelectric conversion can be performed over the wide wavelength range of the sunlight, it is possible to provide a solar cell and a solar cell device having excellent energy conversion efficiency, that is, excellent photoelectric conversion efficiency.

### BRIEF DESCRIPTION OF DRAWINGS

FIG. 1 is a perspective view showing the schematic configurations of a solar cell and a solar cell device according to an embodiment of the present invention.

FIG. 2A is a perspective view illustrating a method for manufacturing the solar cell.

FIG. 2B is a perspective view illustrating the method for manufacturing the solar cell.

FIG. 2C is a perspective view illustrating the method for manufacturing the solar cell.

FIG. 2D is a perspective view illustrating the method for manufacturing the solar cell.

FIG. 3A is a graph illustrating photoelectric conversion efficiency in the solar cell according to the embodiment of the present invention.

FIG. 3B is a graph illustrating photoelectric conversion efficiency in a common tandem solar cell.

FIG. 4 is a perspective view showing the schematic configuration of a solar cell according to a first embodiment of the present invention.

FIG. 5 is a perspective view showing the schematic configuration of a solar cell according to a second embodiment of the present invention.

FIG. 6 is a perspective view showing the schematic configuration of a solar cell according to a third embodiment of the present invention.

FIG. 7 is a perspective view showing the schematic configuration of a solar cell according to a fourth embodiment of the present invention.

FIG. 8 is a perspective view showing the schematic configuration of a modified example of the solar cell according to the fourth embodiment.

### DESCRIPTION OF EMBODIMENTS

The following will describe a solar cell and a solar cell device according to an embodiment of the present invention (corresponding to claims 1 and 5).

First, the basic configurations of the solar cell and the solar cell device using the solar cell will be described.

The solar cell basically includes: a transparent electrode; a plurality of carbon nanotube groups placed in parallel to each other on and perpendicularly to the surface of the transparent electrode, wherein each group contains a number of carbon nanotubes; and metal electrodes as opposite electrodes placed on a side of the carbon nanotube group opposite to the transparent electrode. The diameters of the carbon nanotubes of the carbon nanotube groups are varied stepwise from one side of the transparent electrode to the other side thereof.

In more detail, an n-type semiconductor and a p-type semiconductor are arranged between a pair of electrodes, and at least one of the semiconductors are composed of carbon nanotubes (CNTs). Multiple (at least three) carbon nanotube groups are provided in parallel to each other perpendicularly to the electrode surface (so-called perpendicular orientation). For example, the carbon nanotube groups are separated into multiple areas and lines, and the diameters of the carbon nanotubes are sequentially varied in the respective groups.

Specifically, five areas (may be at least three areas, or at least three lines) containing multiple carbon nanotubes (hereinafter, may be also referred to as tube lines) are located in parallel to each other (side by side), and the diameters of the carbon nanotubes are varied stepwise in the respective tube lines. For example, the carbon nanotubes are placed in order of decreasing diameter.

The electrodes are formed on the upper and lower surfaces of the carbon nanotube groups in the respective tube lines.

As a matter of course, the perpendicular orientation in which the above-described carbon nanotube groups are formed has a tolerance. A line connecting the base to tip of the carbon nanotube may be within the range of, for example, 90°±10° relative to the electrode surface. In other words, the carbon nanotube groups may be formed substantially perpendicular to the electrode surface.

Further, as described above, at least one of the semiconductors are composed of carbon nanotubes. This indicates that the electrodes on one side are formed as semiconductors or a semiconductor layer is formed on one electrode side, and the carbon nanotubes are formed as semiconductors, or alternatively, an n-type semiconductor and a p-type semiconductor are formed in the carbon nanotube groups.

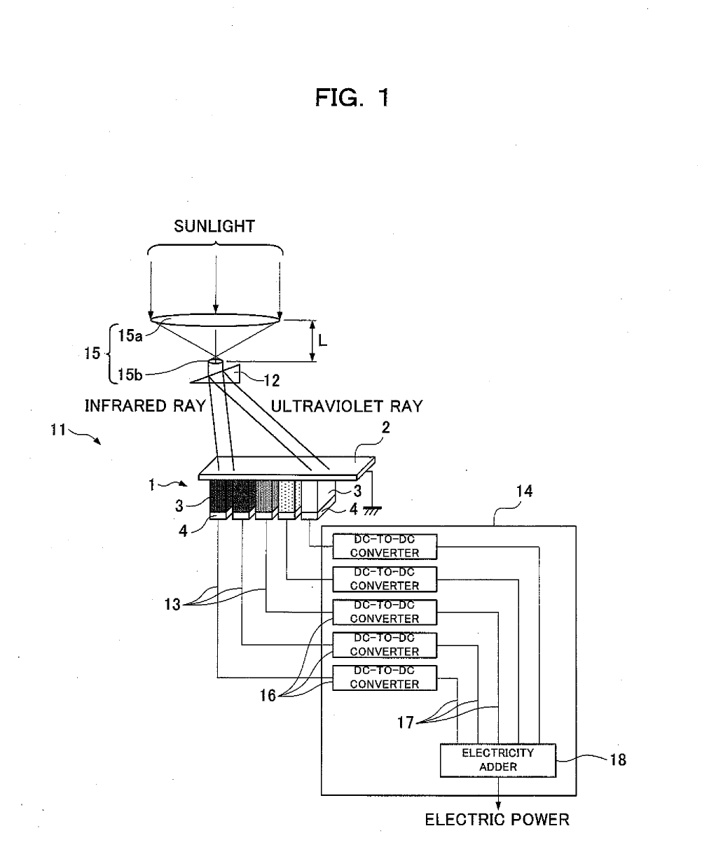

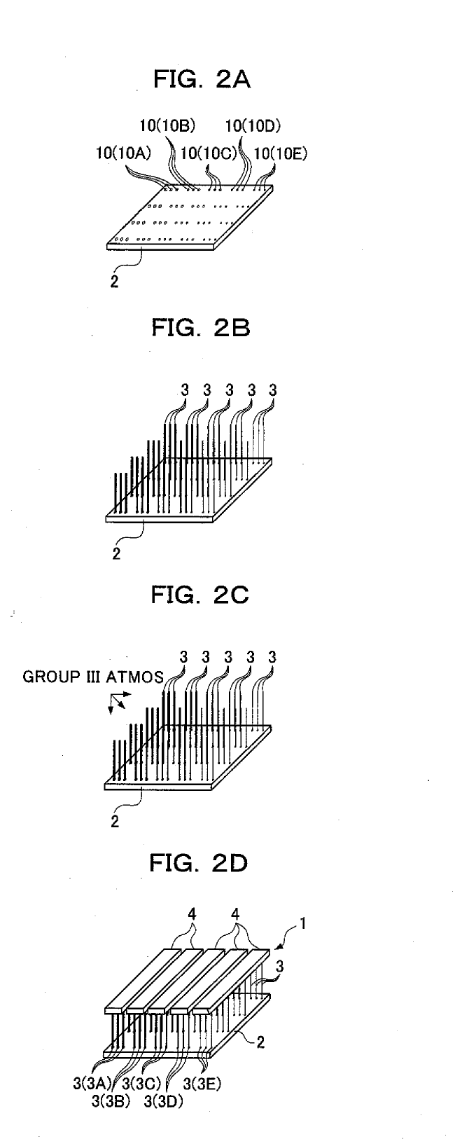

The following will describe a method for manufacturing the solar cell having the above basic configuration with reference to FIGS. 1 and 2A to 2D.

First, the specific configuration of the solar cell will be described on the basis of FIG. 1.

A solar cell 1 includes: a rectangular plate-like transparent electrode 2 formed as an n-type semiconductor; multiple carbon nanotube groups 3 arranged in parallel to each other perpendicularly to the lower surface of the transparent electrode 2; and metal electrodes 4 placed as opposite electrodes on the lower end surfaces (may be also referred to as the surfaces) of the carbon nanotube groups 3. (The upper and lower surfaces of the transparent electrode 2 are specified on the basis of FIG. 1, and specifically, the incidence side of the sunlight is set as the upper side. As a matter of course, the upper and lower surfaces may be reversed, and thus, the lower surface may be simply referred to as the surface of the transparent electrode.) Specifically, the carbon nanotube groups are arranged in at least three (multiple) lines, herein, in five lines.

A spectroscope (may be also referred to as a spectroscopic element) 12 such as a prism for guiding the light beams of the sunlight split in five wavelength ranges to the solar cell 1, and a voltage regulator (serving also as a voltage output circuit) 14 for receiving electric power obtained by the carbon nanotube groups 3 of the solar cell 1 arranged in lines via electric wires 13 and regulating the electric power to a predetermined voltage are provided to configure a solar cell device 11, which will be specifically described later. Further, a condensing lens unit 15 for condensing the sunlight is placed in front of the spectroscope 12.

For example, cylindrical lenses having different sizes are used in the condensing lens unit 15. Specifically, the condensing lens unit 15 includes a first cylindrical lens 15a having a large diameter and a second cylindrical lens 15b having a small diameter. An interval L between the cylindrical lenses is set to a distance obtained by adding a focal length f1 of the first cylindrical lens 15a to a focal length f2 of the second cylindrical lens 15b (L=f1+f2). Thus, the sunlight having entered parallel to the first cylindrical lens 15a enters the second cylindrical lens 15b after being focused once, and then exits as parallel light. At this point, the width of the outgoing parallel light is reduced to f2/f1. Further, the width of the outgoing parallel light should be as small as possible.

The spectroscope 12 allows the parallel light as a split light beam to be incident on the solar cell 1 (exactly on the transparent electrode 2). Desirably, a distance between the spectroscope 12 and the solar cell 1 is set such that the solar cell 1 is smaller in size than the first cylindrical lens 15a. The condensing lens unit 15 having a plurality of cylindrical lenses can guide the sunlight to the solar cell 1 without any waste. The shape of the lens is not limited to this, and may be circular.

Next, the method for manufacturing the solar cell 1 will be schematically described with reference to FIGS. 2A to 2D.

First, as shown in FIG. 2A, a metal [for example, iron (Fe)] thin layer serving as a catalyst is formed on the surface of the transparent electrode 2 (in which fluorine-doped tin oxide, zinc oxide, indium tin oxide, fluorine-doped tin oxide/indium tin oxide, gallium-doped zinc oxide, aluminum-doped zinc oxide or the like is used) of the n-type semiconductor by, for example, sputtering. After that, incisions are made across the length and breadth of the transparent electrode 2 by an electron beam with intervals adjusted therebetween, to form catalytic nanoparticles 10. The iron catalytic nanoparticles 10 are dimensioned in accordance with the diameters of the carbon nanotubes 3 in the respective tube lines. For example, the catalytic nanoparticles are arranged from the left to right of the drawing in order of decreasing diameter size. In other words, the diameters of catalytic nanoparticles 10A on the left are large while the diameters of catalytic nanoparticles 10B to 10E are reduced stepwise toward the right.

Further, in order to dimension the catalytic nanoparticles 10 in accordance with the diameters of the carbon nanotubes 3, the thickness of the thin layer formed by, for example, sputtering may be gradually reduced from the left to the right of the drawing. In the case of sputtering, the thickness of the thin layer can be changed depending on sputtering conditions (sputtering time and a distance between a sputtering source and a thin layer formation surface). Moreover, since a continuous change of the distance between the sputtering source and the thin layer formation surface can change the thickness of the thin layer continuously, the diameters of the carbon nanotubes 3 can be continuously changed.

Next, as shown in FIG. 2B, the carbon nanotubes 3 are formed on the iron catalytic nanoparticles 10 by the thermal chemical vapor deposition method. At this point, the diameters, that is, the thicknesses of the carbon nanotubes 3 formed on the upper surfaces of the catalytic nanoparticles 10 are determined depending on the sizes of the catalytic nanoparticles 10.

As shown in FIG. 2C, the group III atoms of the periodic table are doped into the carbon nanotubes 3 (the thermal chemical vapor deposition method may be implemented with trace gas containing the group III atoms).

As shown in FIG. 2D, the metal electrodes 4 are formed by the physical vapor deposition method on the upper surfaces of the respective tube lines with masking on the electrode boundary portion.

The thermal chemical vapor deposition method will be specifically described.

The iron catalytic nanoparticles are formed on the board of the transparent electrode, and the carbon nanotubes are deposited by supplying source gas to the catalytic nanoparticles as a nucleus in high temperature environment. The catalytic nanoparticles may be made of nickel or cobalt instead of iron.

Specifically, after these metals or the solutions of the compounds such as the complexes of these metals are applied to the board of the transparent electrode by a spray or brush or are beat on the board of the transparent electrode by a cluster gun, drying and, as required, heating are performed to form a layer.

The layer with an excessively large thickness is hardly particulated by heating. Thus, it is preferable that the thickness of the layer fall within the range of 1 nm to 100 nm.

Next, when the layer is heated to the range of 650° C. to 800° C., preferably, under reduced pressure or non-oxidizing atmosphere, iron catalytic nanoparticles having diameters of about 0.1 nm to 50 nm are formed. Further, the catalytic nanoparticles may be formed by sputtering as described above. The source gas of the carbon nanotubes may be aliphatic hydrocarbon such as acethylene, methane, and ethylene, and acethylene is particularly preferable. In acethylene, carbon nanotubes with thicknesses of 0.4 nm to 38 nm are formed brush-like on the transparent electrode with the iron catalytic particles as a nucleus. The carbon nanotubes are preferably formed at 650° C. to 800° C., and are formed by the thermal chemical vapor deposition method in 1 minute to 30 minutes (hereinafter, will be referred to as CVD time).

The physical vapor deposition method for forming the metal electrodes 4 is a vacuum deposition method or a sputtering method.

The following will describe the solar cell device 11 using the above-described solar cell 1.

The spectroscope 12 is placed such that the split light beams of the sunlight are irradiated on tube lines 3A to 3E of the solar cell 1. Thus, the split light beams are guided onto the transparent electrode 2 in the tube lines 3A to 3E for the respective wavelengths of the split light beams.

The voltage regulator 14 is connected to the metal electrodes 4 via the electric wires 13, so that a predetermined voltage can be obtained. Further, the voltage regulator 14 includes DC-to-DC converters 16 connected to the tube lines 3 via the electric wires 13, and an electricity adder 18 connected to the DC-to-DC converters 16 via electric wires 17, so that electric power at the predetermined voltage is outputted. The DC-to-DC converters regulate (convert) voltages from the tube lines 3A to 3E to be the same (the predetermined voltage).

Photoelectric conversion capability, that is, energy band gap in the case that the carbon nanotubes of the carbon nanotube groups 3 have different diameters will be described.

The carbon nanotubes having different diameters are different in band gap. Thus, a carbon nanotube having a band gap equal to energy by of the split light beam of the sunlight may be formed as a p-type or n-type semiconductor.

That is, in the case where there are n carbon nanotubes having different band gaps (the band gaps are represented by Eg₁ to Egₙ, but Egₙ₋₁<Egₙ), light having energy which is smaller than Eg₂ but not smaller than Eg₁ is received by the solar cell having the band gap Eg₁, so that photoelectric conversion is performed. Further, light having energy which is smaller than Eg₃ but not smaller than Eg₂ is received by the solar cell having the band gap Eg₂, so that photoelectric conversion is performed. Similarly, light having maximum energy which exceeds the band gap Egₙ but does not exceed ultraviolet light is received by the solar cell having the band gap Egₙ, so that photoelectric conversion is performed.

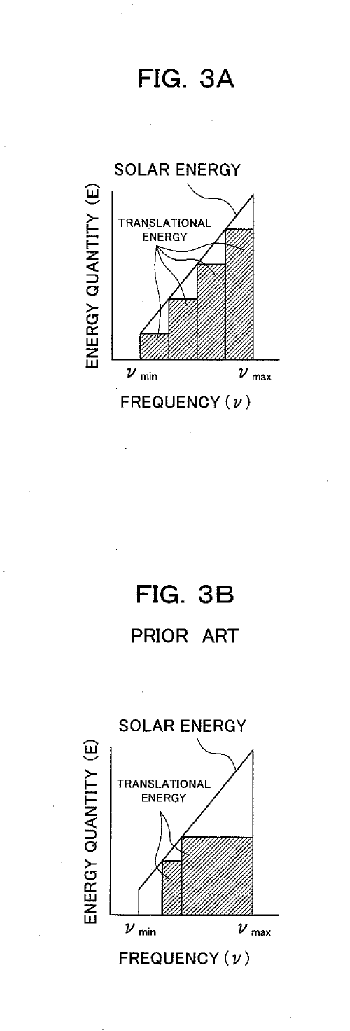

FIG. 3A is a graph showing the amounts of energy which can be photoelectrically converted by using the solar cell having the above configuration. FIG. 3B shows, as a comparative example, the case of a common tandem solar cell of the related art. It can be noted from these graphs that the amounts of energy obtained by varying the diameters of carbon nanotubes stepwise, that is, the amounts of photoelectrically convertible energy are remarkably large.

That is, in the configuration of the solar cell, the carbon nanotubes are placed between the transparent electrode and the metal electrodes, and the diameters of the carbon nanotubes are varied stepwise. Thus, it is possible to form carbon nanotubes having band gaps for the respective wavelengths of, for example, the split light beams of the sunlight. Accordingly, since photoelectric conversion can be performed over the wide wavelength range of the sunlight, it is possible to provide a solar cell having excellent energy conversion efficiency, that is, excellent photoelectric conversion efficiency.

The above-described solar cell device uses a single solar cell. As a matter of course, multiple solar cells can be provided to obtain a large amount of electric power. In this case, the voltage regulators of the solar cells can be integrated into a single unit.

In the above description, the diameters of the carbon nanotubes are adjusted in accordance with the sizes of the catalytic nanoparticles. The diameters can be controlled even by, for example, adjusting the CVD time.

Specific examples, that is, embodiments of the solar cell will be described below.

### First Embodiment

The following will describe a solar cell according to a first embodiment (corresponding to claims 1 and 2) of the present invention.

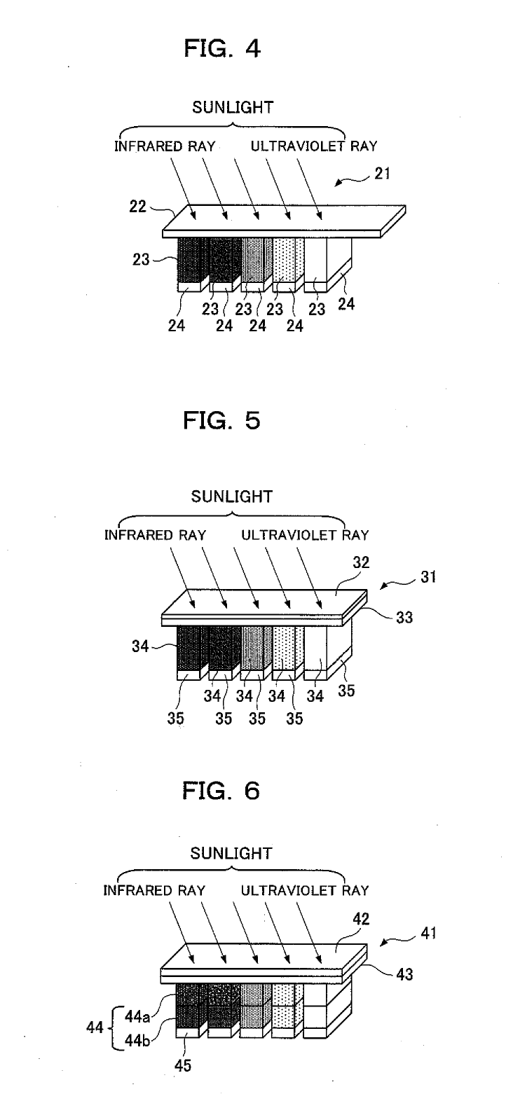

As shown in FIG. 4, a solar cell 21 includes: a transparent electrode (for example, a fluorine-doped tin oxide electrode) 22 formed as an n-type semiconductor; a plurality of carbon nanotube groups 23 placed in parallel to each other on and perpendicularly to the lower surface (surface) of the transparent electrode 22; and metal electrodes 24 placed as opposite electrodes on the lower surfaces (surfaces) of the carbon nanotube groups 23 opposite to the transparent electrode 22. The diameters of the carbon nanotubes of the side-by-side carbon nanotube groups 23 are varied stepwise from one side of the electrode 22 to the other side of the electrode 22, and the group III atoms of the periodic table are doped into the carbon nanotube groups 23 to form p-type semiconductors.

A method for manufacturing the solar cell 21 will be described.

Iron (Fe) catalytic nanoparticles (may be platinum or cobalt nanoparticles instead) having different sizes are formed on the surface of the transparent electrode 22 of the n-type semiconductor. Further, the sizes are divided into five stages, that is, the nanoparticles are provided in five lines as described above.

The sizes of the catalytic nanoparticles are varied by the following two methods.

(1) After a metal thin layer as a catalyst is formed on the transparent electrode, incisions are made across the length and breadth of the transparent electrode by an electron beam with intervals adjusted therebetween, to form catalytic nanoparticles. In adjusting the intervals, the sizes and shapes of the nanoparticles are adjusted by heating.

(2) A metal thin layer as a catalyst is formed on the surface of the transparent electrode by sputtering. In forming the thin layer, a distance between the metal source and the transparent electrode is varied, so that catalytic nanoparticles having different diameters are formed.

Next, the carbon nanotube groups 23 are formed by the thermal chemical vapor deposition method on the catalytic nanoparticles formed on the surface of the transparent electrode 22. In other words, the carbon nanotubes of the carbon nanotube groups 23 are deposited.

For example, when the transparent electrode 22 is heated and supplied with pyrolytic hydrocarbon gas such as pyrolytic C₂H₂ gas and CH₄ gas, the carbon nanotubes of the carbon nanotube groups 23 are deposited from the catalytic nanoparticles. As a matter of course, the diameters (thicknesses) of the deposited carbon nanotubes of the carbon nanotube groups 23 depend on the sizes of the catalytic nanoparticles.

As described above, the diameters of the carbon nanotubes may be varied by changing the CVD time instead of the sizes of the catalytic nanoparticles. Specifically, when the CVD time is short, the carbon nanotubes are thin with a low number of layers, and when the CVD time is long, the carbon nanotubes are thick with multiple layers. Thus, the thicknesses of the carbon nanotubes can be adjusted by the CVD time. Further, the thick carbon nanotubes have a multi-layered structure, but the band gap of the carbon nanotube of the outermost layer is used.

Next, the group III atoms of the periodic table (such as boron, aluminum, gallium, indium, and titanium) are doped into the carbon nanotube groups 23 to form p-type semiconductors. In detail, gas containing the group III atoms such as diborane (B₂H₆) gas is thermally decomposed and sprayed to the carbon nanotube groups 23. In the step of forming the carbon nanotube groups 23, a trace of the gas containing the group III atoms may be mixed in the hydrocarbon gas.

Next, when the metal electrodes 24 are formed for the respective carbon nanotube groups 23 having carbon nanotubes with different diameters, that is, the respective tube lines, the solar cell 21 can be obtained.

Specifically, after masking is applied to separate the respective tube lines, metal such as copper, gold, silver, and aluminum is attached to the upper ends of the carbon nanotube groups 23, to which masking cannot be applied, by the physical vapor deposition method. Instead of the physical vapor deposition method, thermal vacuum deposition, deposition with an electron beam, and sputtering may be adopted.

### Second Example

The following will describe a solar cell according to a second embodiment of the present invention (corresponding to claim 2).

As shown in FIG. 5, a solar cell 31 includes: a transparent board 32 formed of silicon dioxide (SiO₂); a transparent electrode (for example, a fluorine-doped tin oxide electrode) 33 formed as an n-type semiconductor on the lower surface (surface) of the transparent board 32; a plurality of carbon nanotube groups 34 placed in parallel to each other on and perpendicularly to the lower surface (surface) of the transparent electrode 33; and metal electrodes 35 placed as opposite electrodes on the lower surfaces (surfaces) of the carbon nanotube groups 34 opposite to the transparent electrode 33. The diameters of the carbon nanotubes of the carbon nanotube groups 34 in parallel to each other are varied, for example, are reduced stepwise from one side toward the other side, and the group III atoms of the periodic table are doped into the carbon nanotube groups 34 to form p-type semiconductors.

A method for manufacturing the solar cell 31 will be described.

The manufacturing method will be schematically described since it is basically the same as that in the first embodiment.

First, the transparent electrode 33 of the n-type semiconductor is formed on the surface of the transparent board 32 of silicon dioxide.

Next, catalytic nanoparticles having different sizes such as iron, platinum, and cobalt are formed on the surface of the transparent electrode 33. The sizes of the catalytic nanoparticles are divided into five stages as described above, that is, the catalytic nanoparticles having different sizes are formed in five lines.

The carbon nanotube groups 34 are formed, by the thermal chemical vapor deposition method, on the catalytic nanoparticles formed on the surface of the transparent electrode 33 by the same method as in the first embodiment.

The group III atoms such as boron, aluminum, gallium, indium, and titanium are doped into the carbon nanotube groups 34 to form p-type semiconductors.

The metal electrodes 35 are formed for the respective tube lines having different diameters by, for example, sputtering to obtain the solar cell 31.

A brief description of the manufacturing method is given as follows:

In the method for manufacturing the solar cell, a plurality of carbon nanotube groups are formed in parallel to each other on and perpendicularly to the surface of the transparent electrode of the n-type semiconductor such that the diameters of the carbon nanotubes of the carbon nanotube groups are varied stepwise from one side of the electrode to the other side of the electrode, the group III atoms of the periodic table are doped into the carbon nanotube groups to form p-type semiconductors, and metal electrodes are formed on the end surfaces of the carbon nanotube groups. Contrary to the above description, a transparent electrode may be formed by sputtering on the end surfaces of carbon nanotubes formed beforehand.

### Third Embodiment

The following will describe a solar cell according to a third embodiment of the present invention (corresponding to claim 3).

As shown in FIG. 6, a solar cell 41 includes: a transparent board 42 formed of silicon dioxide (SiO₂); a transparent electrode (for example, a fluorine-doped tin oxide electrode) 43 formed as an n-type semiconductor on the lower surface (surface) of the transparent board 42; a plurality of carbon nanotube groups 44 placed in parallel to each other on and perpendicularly to the lower surface (surface) of the transparent electrode 43; and metal electrodes 45 placed as opposite electrodes on the lower surfaces (surfaces) of the carbon nanotube groups 44 opposite to the transparent electrode 43. The group V atoms of the periodic table are doped into transparent-electrode-side portions 44a of the carbon nanotube groups 44 to form n-type semiconductors, and the group III atoms of the periodic table are doped into metal-electrode-side portions 44b of the carbon nanotube groups 44 to form p-type semiconductors. Further, the diameters of the carbon nanotubes of the carbon nanotube groups 44 in parallel to each other are varied stepwise from one side of the electrode toward the other side of the electrode.

The following will describe a method for manufacturing the solar cell 41.

First, the transparent electrode 43 is formed by sputtering on the surface of the transparent board 42 of silicon dioxide.

Next, iron catalytic nanoparticles are formed on the surface of the transparent electrode 43 by sputtering.

The carbon nanotube groups 44 are then formed on the catalytic nanoparticles by, for example, the thermal chemical vapor deposition method. At this point, a trace of phosphine (PH₃) is added to form the transparent-electrode-side portions 44a of the carbon nanotube groups 44 as the n-type semiconductors.

Further, the p-type semiconductor portions 44b are formed on the end surfaces of the n-type semiconductor portions 44a. At this point, a trace of diborane (B₂H₆) is added to form p-type semiconductors. In other words, the metal-electrode-side portions 44b of the carbon nanotube groups 44 are formed as the p-type semiconductors.

The metal electrodes 45 are formed of, for example, aluminum for the respective carbon nanotube groups 44 having carbon nanotubes with different diameters, that is, the respective tube lines.

In the third embodiment, the transparent electrode 43 is placed on the surface of the transparent board 42, but as a matter of course, only the transparent electrode may be provided.

A brief description of the manufacturing method is given as follows:

In the method for manufacturing the solar cell, a plurality of carbon nanotube groups are formed in parallel to each other between the transparent electrode on one side and the metal electrodes on the other side and perpendicularly to the surfaces of the electrodes such that the diameters of the carbon nanotubes of the carbon nanotube groups are varied stepwise from one side to the other side. The group V atoms of the periodic table are doped into the transparent-electrode-side portions of the carbon nanotube groups to form n-type semiconductors, and the group III atoms of the periodic table are doped into the metal-electrode-side portions of the carbon nanotube groups to form p-type semiconductors.

### Fourth Embodiment

The following will describe a solar cell according to a fourth embodiment of the present invention (corresponding to claim 4).

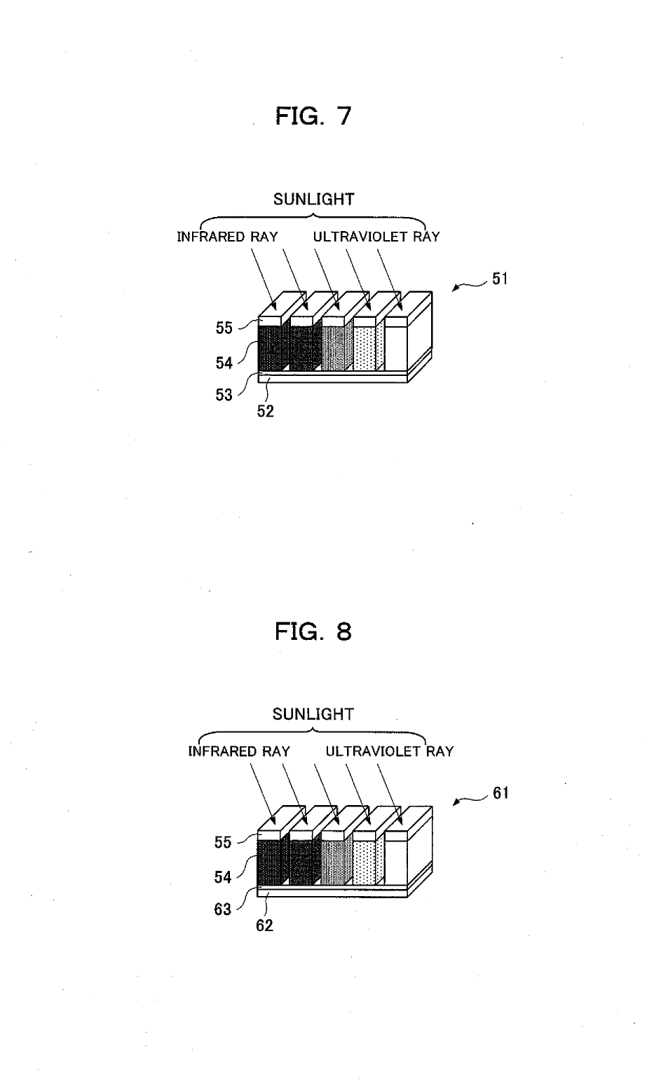

As shown in FIG. 7, a solar cell 51 includes: a metal electrode 52 made of SUS (JIS code of stainless steel) or the like; a p-type semiconductor board (p-type semiconductor layer) 53 placed on the surface of the metal electrode 52 and doped with, for example, boron (B) atoms of the group III of the periodic table; a plurality of carbon nanotube groups 54 placed in parallel to each other on and perpendicularly to the surface of the p-type semiconductor board 53; and transparent electrodes (such as fluorine-doped tin oxide electrodes) 55 formed as opposite electrodes on the surfaces of the carbon nanotube groups 54 opposite to the metal electrode 52. The diameters of the carbon nanotubes of the carbon nanotube groups 54 in parallel to each other are varied stepwise from one side to the other side, and the carbon nanotubes 53 are doped with, for example, phosphorous (P) atoms of the group V of the periodic table to form n-type semiconductors.

A method for manufacturing the solar cell 51 will be described.

The manufacturing method will be schematically described since it is basically the same as that in the first embodiment.

For example, on the surface of the metal electrode 52 formed of a rectangular stainless steel (SUS) plate or the like, the p-type semiconductor board 53 is formed by doping, for example, boron (B) atoms of the group III of the periodic table into a board of silicon or the like.

Next, iron catalytic nanoparticles (may be platinum or cobalt instead) having different diameters are formed on the surface of the p-type semiconductor board 53. As described above, the sizes of the catalytic nanoparticles are divided into five stages, that is, the catalytic nanoparticles having different sizes are provided in five lines.

The carbon nanotube groups 54 are formed, by the thermal chemical vapor deposition method, on the catalytic nanoparticles formed on the surface of the p-type semiconductor board 53 by the same method as in the first embodiment.

The group V atoms of the periodic table such as phosphorus atoms are doped into the carbon nanotube groups 54 to form the n-type semiconductors.

The transparent electrodes 55 are then formed on the respective tube lines having different diameters by, for example, sputtering. Thus, the solar cell 51 can be obtained.

In the fourth embodiment, as described above, since the transparent electrodes 55 are formed after the carbon nanotube groups 54 are formed, it is possible to use indium tin oxide which is difficult to apply at high temperature in the thermal chemical vapor deposition method.

A brief description of the manufacturing method is given as follows:

In the method for manufacturing the solar cell, a p-type semiconductor layer is formed on the surface of the metal electrode, a plurality of carbon nanotube groups are formed in parallel to each other on and perpendicularly to the surface of the p-type semiconductor layer such that the diameters of the carbon nanotubes of the carbon nanotube groups are varied stepwise from one side of the metal electrode to the other side of the metal electrode, the group V atoms of the periodic table are doped into the carbon nanotube groups to form n-type semiconductors, and transparent electrodes are formed on the end surfaces of the carbon nanotube groups.

Instead of the metal electrode 52 and the p-type semiconductor board 53 of the solar cell according to the fourth embodiment, as shown in FIG. 8, a metal electrode 62 formed of copper or the like and a metal board 63 formed of molybdenum or the like can be used to obtain a solar cell 61.

In the above-described embodiments, the groups of carbon nanotubes having different band gaps (that is, different diameters) are sequentially formed on the surface of the electrode. However, the groups of carbon nanotubes formed beforehand for the respective different band gaps on the surface of the electrode may be sequentially combined to manufacture a solar cell.

### INDUSTRIAL APPLICABILITY

According to the present invention, since the carbon nanotube groups are placed between the transparent electrode and the metal electrodes and the diameters of the carbon nanotubes are varied stepwise, it is possible to form carbon nanotubes having any band gaps in accordance with the respective wavelengths of, for example, split light beams of the sunlight. Thus, photoelectric conversion can be performed over the wide wavelength range of the sunlight, so that it is possible to provide a solar cell excellent in energy conversion efficiency.

1. A solar cell comprising:
a transparent electrode;
a plurality of carbon nanotube groups placed in parallel to each other on and perpendicularly to a surface of the transparent electrode, wherein each group contains a number of carbon nanotubes; and
metal electrodes placed on the carbon nanotube groups opposite to the transparent electrode, wherein diameters of the carbon nanotubes of the carbon nanotube groups in parallel to each other are varied stepwise from one side of the transparent electrode to another side thereof.

2. The solar cell according to claim 1, wherein the transparent electrode is formed as an n-type semiconductor, and group III atoms of a periodic table are doped into the carbon nanotube groups to form p-type semiconductors.

3. The solar cell according to claim 1, wherein group V atoms of a periodic table are doped into transparent-electrode-side portions of the carbon nanotube groups to form n-type semiconductors, and group III atoms of the periodic table are doped into metal-electrode-side portions of the carbon nanotube groups to form p-type semiconductors.

4. The solar cell according to claim 1, wherein group V atoms of a periodic table are doped into the carbon nanotube groups to form n-type semiconductors, and a p-type semiconductor layer is placed between the metal electrodes and the carbon nanotube groups.

5. A solar cell device using the solar cell according to any one of claims 1 to 4, the solar cell device comprising: a spectroscope for splitting sunlight being placed on the surface of the transparent electrode of the solar cell; and a voltage regulator for regulating electric power obtained by the carbon nanotube groups of the solar cell to a predetermined voltage.
